(19) United States
(12) Patent Application Publication
(10) Pub. No.: US 2024/0332327 A1
(43) Pub. Date: Oct. 3, 2024

(54) IMAGE SENSOR PACKAGES AND RELATED METHODS

(71) Applicant: SEMICONDUCTOR COMPONENTS INDUSTRIES, LLC, Scottsdale, AZ (US)

(72) Inventors: Kazumi ONDA, Saitama (JP); Jason Paul GOODELLE, San Jose, CA (US)

(73) Assignee: SEMICONDUCTOR COMPONENTS INDUSTRIES, LLC, Scottsdale, AZ (US)

(21) Appl. No.: 18/602,261

(22) Filed: Mar. 12, 2024

Related U.S. Application Data
(60) Provisional application No. 63/493,827, filed on Apr. 3, 2023.

(51) Int. Cl. H01L 27/146

(52) U.S. Cl. CPC H01L 27/14621; H01L 27/14685

(57) ABSTRACT

An image sensor package may include an image sensor die; an electromagnetic radiation transmissive cover coupled over the image sensor die; and a dam between the image sensor die and the electromagnetic radiation transmissive cover, the dam including a colored additive. The dam may form a space between the image sensor die and the electromagnetic radiation transmissive cover.

### CROSS REFERENCE TO RELATED APPLICATIONS

This document claims the benefit of the filing date of U.S. Provisional Patent Application 63/493,827, entitled “Sensing Package” to Onda et al. which was filed on Apr. 3, 2023, the disclosure of which is hereby incorporated entirely herein by reference.

### BACKGROUND

### 1. Technical Field

Aspects of this document relate generally to semiconductor device packages. More specific implementations involve packages for image sensor semiconductor devices.

### 2. Background

Various semiconductor packages have been devised to allow for formation of electrical interconnects between a semiconductor die and a motherboard or circuit board to which the semiconductor packages are attached. Other semiconductor packages work to provide mechanical support to a semiconductor die. Some semiconductor packages work to help prevent damage to the semiconductor die from humidity or shock and vibration.

### SUMMARY

An image sensor package may include an image sensor die; an electromagnetic radiation transmissive cover coupled over the image sensor die; and a dam between the image sensor die and the electromagnetic radiation transmissive cover, the dam including a colored additive. The dam may form a space between the image sensor die and the electromagnetic radiation transmissive cover.

Implementations of an image sensor package may include one, all, or any of the following:

The colored additive may make the dam optically opaque to one or more wavelengths of electromagnetic radiation detected by the image sensor die. Package.

The colored additive may make the dam optically opaque to ultraviolet light wavelengths.

The colored additive may make the dam optically opaque to infrared light wavelengths.

The colored additive may make the dam optically opaque to visible light wavelengths.

The dam may fixedly couple the image sensor die and the electromagnetic radiation transmissive cover together.

The package may include a substrate coupled to the image sensor die.

The package may include an adhesive material that fixedly couples the image sensor die, the dam, and the electromagnetic radiation transmissive cover together.

Implementations of a method of forming an image sensor package include providing an image sensor die; forming a dam on an electromagnetic radiation transmissive cover; placing the electromagnetic radiation transmissive cover over the image sensor die; fixedly coupling the image sensor die to the electromagnetic radiation transmissive cover by curing a material of the dam; and preventing one or more wavelengths of light from passing through the dam using a colored additive included in the dam.

Implementations of a method of forming an image sensor package may include one, all, or any of the following:

The method may include coupling a substrate to the image sensor die.

The method may include applying a mold compound to the image sensor die, the dam, and the electromagnetic radiation cover.

The colored additive may make the dam optically opaque to ultraviolet light wavelengths.

The colored additive may make the dam optically opaque to infrared light wavelengths.

The colored additive may make the dam optically opaque to visible light wavelengths.

Implementations of a method of forming an image sensor package may include providing an image sensor die; forming a dam on an electromagnetic radiation transmissive cover; applying an adhesive material to the image sensor die; placing the electromagnetic radiation transmissive cover over the image sensor die; fixedly coupling the image sensor die to the electromagnetic radiation transmissive cover by curing the adhesive material; and preventing one or more wavelengths of light from passing through the dam using a colored additive included in the dam.

Implementations of a method of forming an image sensor package may include one, all, or any of the following:

The method may include coupling a substrate to the image sensor die.

The method may include applying a mold compound to the image sensor die, the dam, and the electromagnetic radiation cover.

The colored additive may make the dam optically opaque to one of infrared light wavelengths or ultraviolet light wavelengths.

Curing the adhesive material further may include only thermally curing the adhesive material.

The colored additive may make the dam optically opaque to visible light wavelengths.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of an image sensor package with a light block layer;

FIG. 2 is a cross sectional view of an implementation of an image sensor package with a dam;

FIG. 3 is a cross sectional view of an implementation of an image sensor die after bonding/attaching to a substrate and wirebonding;

FIG. 4 is a cross sectional view of an implementation of an electromagnetic radiation transmissive cover after formation of a dam thereon;

FIG. 5 is a cross sectional view of the image sensor of FIG. 3 following placing of the electromagnetic radiation transmissive cover of FIG. 4 thereon;

FIG. 6 is a cross sectional view of the image sensor package of FIG. 5 following bonding of the dam to the image sensor die and application of a mold compound thereto;

FIG. 7 is a cross sectional view of an implementation of an image sensor die after bonding/attaching to a substrate and wirebonding;

FIG. 8 is a cross sectional view of an implementation of an electromagnetic radiation transmissive cover after formation of a dam thereon;

FIG. 9 is a cross sectional view of the image sensor of FIG. 7 following application of an adhesive material thereto;

FIG. 10 is a cross sectional view of the image sensor of FIG. 7 following placing of the electromagnetic radiation transmissive cover of FIG. 8 thereon; and

FIG. 11 is a cross sectional view of the image sensor package of FIG. 10 following bonding of the dam to the image sensor die and application of a mold compound thereto.

### DESCRIPTION

This disclosure, its aspects and implementations, are not limited to the specific components, assembly procedures or method elements disclosed herein. Many additional components, assembly procedures and/or method elements known in the art consistent with the intended image sensor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor packages, and implementing components and methods, consistent with the intended operation and methods.

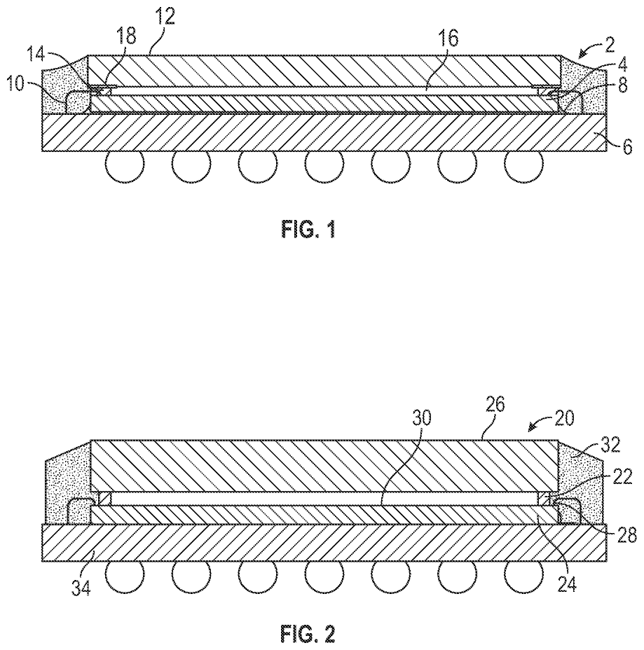

Referring to FIG. 1, a cross sectional view of an implementation of an image sensor package 2 is illustrated. In this implementation, an image sensor die 4 is coupled to substrate 6 through a die attach/die bonding material 8. In this implementation the substrate 8 includes a plurality of solder balls attached thereto and so this particular image sensor package 2 is a ball grid array (BGA) package. Electrical connections between die pads (not visible in FIG. 1) on the image sensor die 4 and corresponding pads on the substrate 8 are formed using wirebonds 10. Electromagnetic radiation transmissive cover 12 is attached to the image sensor die 4 over the wirebonds 10 and pads using adhesive material 14 which also forms a spacer or dam that creates an air gap 16. A black layer/light block layer 18 is present between the adhesive material 14 and the electromagnetic radiation transmissive cover 12 and works to prevent undesired electromagnetic radiation of one or more wavelengths to scatter from the wirebonds/pads and be received by the pixels of the image sensor die 4. A mold compound is also applied around the edge of the package to protect the wirebonds and further secure the joint between the electromagnetic radiation transmissive cover 12, the image sensor die 4, and the adhesive material 14. This type of image sensor package can be referred to as a wire-in-dam package where the adhesive material acts both as the dam and adhesive and the wirebonds/bond wires are embedded in the material.

In various image sensor packages with this structural design, the adhesive material is applied in a liquid/flowable form so as to flow around the wirebonds without causing voids and then is cured to harden it and form a secure bond between the electromagnetic radiation transmissive cover 12 and the image sensor die 4. In some implementations, the adhesive material is cured to a first tacky B-stage using ultraviolet light to ensure that the joint between the electromagnetic radiation transmissive cover 12 and the image sensor die 4 is sufficiently strong before the package 2 is heated in a thermal curing step to complete the final curing of the adhesive material to a hardened C-stage. Without the use of the ultraviolet light curing process, during the thermal curing process bubbles, voids, or a separation between the electromagnetic radiation transmissive cover and/or the image sensor die may take place, which can cause immediate failures or longer-term reliability problems.

Because the black layer 18 is present directly above the adhesive material 14, the ability of ultraviolet light oriented top down to expose the adhesive material 14 is essentially eliminated, and so the ultraviolet light used to cure the adhesive material 14 is that which comes from each side of the package, which provides attenuated irradiation intensity. Furthermore, observations of location specific failures of wirebonds have indicated that the adhesive material 14 is unevenly cured around the perimeter of the image sensor die 4, creating locations where ionic contaminants like chlorine in the uncured adhesive material 14 have the ability to migrate to the wirebond joint itself and participate in corrosion reactions prior to and after operation. Higher voltage pads appear to be more sensitive to this corrosion effect due to the higher electric field involved in these joints.

Eliminating the black layer 18 would permit more even curing of the adhesive material 14, but unfortunately, would result in an increase in light scattering defects in the images produced by the image sensor 4 caused by light reflected from the wirebonds and pads in the otherwise optically transparent material of the dam. Thus, in the structure of this particular package design, a black layer 18 that is as wide as or wider than the adhesive material 14 is used to minimize the number of possible light scattering defects. However, a black layer of this size around the perimeter of the electromagnetic radiation transmissive cover also minimizes the amount of ultraviolet light available to cure the adhesive material 14.

Referring to FIG. 2, another implementation of an image sensor package 20 is illustrated. In this implementation, a dam 22 is located between image sensor die 24 and electromagnetic radiation transmission cover 26. In this implementation, no black layer is present and the dam 22 is located between the wirebonds 28 and the pixel array 30 of the image sensor die 24. In this implementation, the dam 22 includes a colored additive that makes the material of the dam optically opaque to one or more wavelengths of electromagnetic radiation that is detectable by the pixel array 30 of the image sensor die 24. In some implementations, the colored additive may make the dam 22 optically opaque to ultraviolet light wavelengths. In other implementations, the colored additive may make the dam 22 optically opaque to infrared light wavelengths. In yet other implementations, the colored additive may make the dam 22 optically opaque to visible light wavelengths. In yet other implementations, the colored additive may make the dam 22 optically opaque to any combination of the wavelengths of ultraviolet light, infrared light, visible light, or all of the foregoing. For example, where the colored additive turns the color of the dam 22 visibly black, this may be sufficient for the dam 22 to prevent transmission of ultraviolet, infrared, and visible light through the material of the dam 22.

The particular color of the colored additive may be a function of the particular wavelength of electromagnetic radiation that is desired to be blocked/absorbed. In particular implementations, the colored additive may turn the color of the material of the dam 22, by non-limiting example, black, blue, red, purple, green, gray, opaque white, or any other desired color capable of blocking/absorbing the desired wavelength(s) of electromagnetic radiation. The colored additive may be added during manufacture of the material of the dam in various system and method implementations to create material for specific image sensor packages designed to receive and process specific wavelengths of electromagnetic radiation.

Because the dam 22 is located between the wirebonds 28 and pads and the pixel array 30, reflected electromagnetic radiation from the wirebonds 28 and pads is blocked from being received by the pixel array by the material of the dam 22. In this implementation, a higher dam may be more effective in blocking reflected electromagnetic radiation in combination with the particular color of the colored additive used. The effectiveness may also increase where an electromagnetic radiation opaque mold compound 32 is used to cover the wirebonds 28 and the edges/sidewalls of the electromagnetic radiation transmissive cover 26, dam 22, and image sensor die 24. This helps ensure that the only light that enters the material of the electromagnetic radiation transmissive cover 26 is reflected at a fairly high angle relative to the surface of the pixel array 30 and thus is now unlikely to be able to reach the pixel array 30.

This ability of the dam with the colored additive to block reflected light from the wirebonds and pads means that the issues of ultraviolet cure of an adhesive material are eliminated. In this particular implementation, no adhesive material is used as the material of the dam 22 itself is what is used to form the fixed bond between the electromagnetic radiation transmissive cover 26 and the image sensor die 24. Because of this, corrosion of wirebonds caused by ion migration in incompletely cured adhesive material can also be eliminated. Like the image sensor package implementation of FIG. 1, the illustrated image sensor package 20 also includes a substrate 34. However, in some implementations, a substrate may not be included. Various methods of forming image sensor packages like those disclosed here will be discussed in this document.

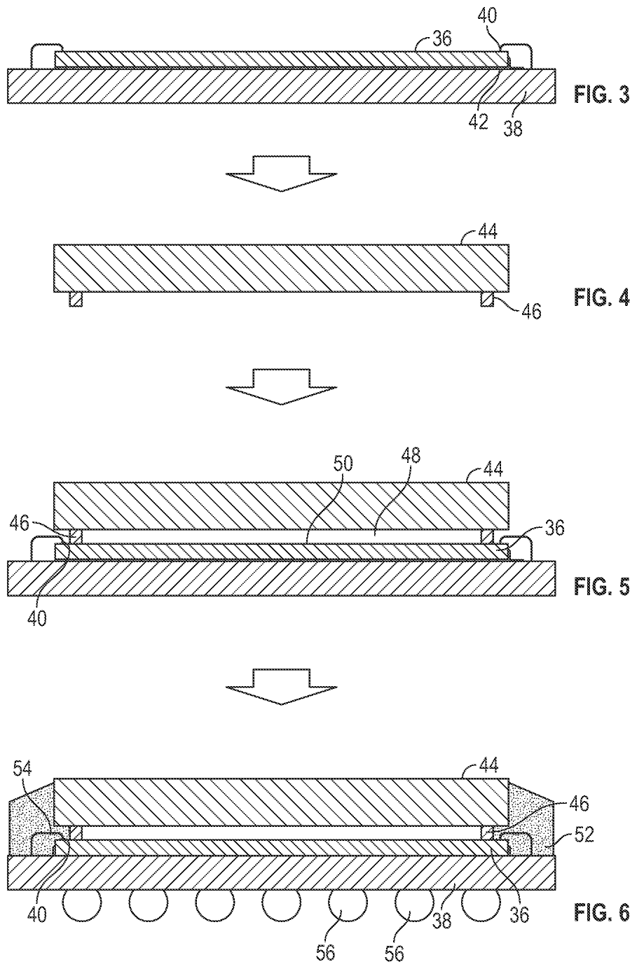

Referring to FIG. 3, an implementation of an image sensor die 36 is illustrated following bonding/attaching to a substrate 38 and completion of formation of wirebonds 40 between pads on the image sensor die 36 and the substrate 38. Here a die attach/die bonding material 42 is used to form the bond between the image sensor die 36 and the substrate 38. The substrate 38 at this point is illustrated without solder balls as these will be added in a later processing step.

Referring to FIG. 4, an implementation of an electromagnetic radiation transmissive cover 44 is illustrated following formation of a dam 46 thereon. The dam 46 includes a colored additive like any disclosed in this document. The dam 46 can be formed using, by non-limiting example, a photolithography/etching process, a dispensing process, a screen printing process, a stenciling process or another process consistent with the particular material of the dam itself. In various implementations, the material of the dam 46 may include, by non-limiting example, an epoxy, a resin, a polymer, any combination thereof, or any other material capable of forming a fixed bond between the material of the electromagnetic radiation transmissive cover 44 and the image sensor die 36. While the cross sectional view in FIG. 4 shows the dam 46 on two sides of the electromagnetic radiation transmissive cover 44, it is understood that the dam 46 is formed around the entire perimeter of the electromagnetic radiation transmissive cover 44 so as to form a seal with the image sensor die 36.

Referring to FIG. 5, the image sensor die 36 is illustrated following placing of the electromagnetic radiation transmissive cover 44 over it with the dam 46 contacting both. In this situation, in particular method implementations, the material of the dam 46 may be cured to a B-stage where it has sufficient stiffness and stickiness/tackiness to adhere to the image sensor die 36 to retain alignment during subsequent processing while forming air gap 48. Note that the position of the dam 46 on the electromagnetic radiation transmissive cover 44 is designed so that the dam 46 rests between the wirebonds 40 and the pixel array 50 of the image sensor die 36.

Referring to FIG. 6, the image sensor die 36 is illustrated following thermal curing of the material of the dam 46 to form a fixed bond between the image sensor die 36 and the electromagnetic radiation transmissive cover 44 (to a C-stage, depending on the material of the dam 46). Following the thermal curing, a mold compound 52 has been applied around the sidewalls/edges of the electromagnetic radiation transmissive cover 44, image sensor die 36, and the dam 46. The mold compound 46 also encloses the wirebonds 40 and bond wires 54. The image sensor package implementation illustrated in FIG. 6 also shows the substrate 38 following a ball drop/ball attach operation in which a plurality of solder balls 56 have been attached to pads in the substrate 38. While the use of balls is illustrated in the ball grid array image sensor package implementation of 56, in other implementations no balls may be used and the package may employ just pads (as in a land grid array package design), leads, or pins (as in a pin grid array package).

The image sensor package implementation of FIG. 6, which employs the material of the dam 46 itself to form the bond between the electromagnetic radiation transmissive cover 44 and the image sensor die 36, does not utilize any separate adhesive material. Thus, since the material of the dam 46 is thermally cured only when reaching the C-stage, any issues with incomplete ultraviolet light curing when the electromagnetic radiation transmissive cover 44 are avoided. Because of this, this image sensor package implementation may see no wirebond corrosion while avoiding image defects caused by scattered light from the wirebonds/bond wires/pads. In various implementations, while the presence of an air gap 48 is illustrated in the package implementation of FIG. 6, the foregoing method implementation could also be used in gapless image sensor packages where a material of a desired refractive index is applied to the electromagnetic radiation transmissive cover 44 prior to placing of the cover over the image sensor die 36.

Referring to FIG. 7, another implementation of an image sensor die 58 is illustrated after bonding/attaching to substrate 60 using die attach/bonding material 62. Wirebonds 64 with bond wires 66 have also been formed between corresponding pads on the image sensor die 58 and the substrate 60. Referring to FIG. 8, an implementation of an electromagnetic radiation transmissive cover 68 is illustrated following formation of a dam 70 thereof. The dam 70 includes a colored additive which may be any disclosed in this document. In this method implementation, the material of the dam 70 has been fully cured (C-stage) as the material of the dam 70 is not used as the sole bonding/attaching material between the electromagnetic radiation transmissive cover 68 and the image sensor die 58. The dam 70 may be formed using any process previously disclosed in this document with the addition that instead of curing to a tacky stage (B-stage), the curing processed used takes the material of the dam 70 to a fully cured stage (C-stage).

Referring to FIG. 9, the image sensor die 58 is illustrated following application of an adhesive material 72 thereto between the wirebonds 64 and the pixel array 74 of the image sensor die 58. In this method implementation, the adhesive material 72 is one that is thermally cured only and since it is designed to bond to the material of the dam 70 and to the image sensor 58 rather than to the electromagnetic radiation transmissive cover 68, the need for the adhesive material 72 to be cured to a B-stage prior to the thermal cure step may be eliminated, as the adhesive material 72 needs to yield around the material of the dam 70 when the dam 70 is pressed down into it.

Referring to FIG. 10, the dam 70 is illustrated following placing of the electromagnetic radiation transmissive cover 68 over the image sensor 58 and thermal curing of the adhesive material 72 which is no longer visible in this view. An air gap 76 is present between the electromagnetic radiation transmissive cover 68 and the image sensor 58. The ability to use adhesive material 72 to secure the dam 70 to the image sensor 58 may allow for accurate processing during thermal curing without creating voids or bubbles due to the low amount of adhesive material 72 needed to complete the formation of the bond. As previously discussed, while an air gap 76 is illustrated in FIG. 10, in other implementations a gapless image sensor may be formed by adding a material of a desired refractive index over the pixel array 74 of the image sensor die 58 after application of the adhesive material 72 and before placing of the electromagnetic radiation transmissive cover 68 thereon.

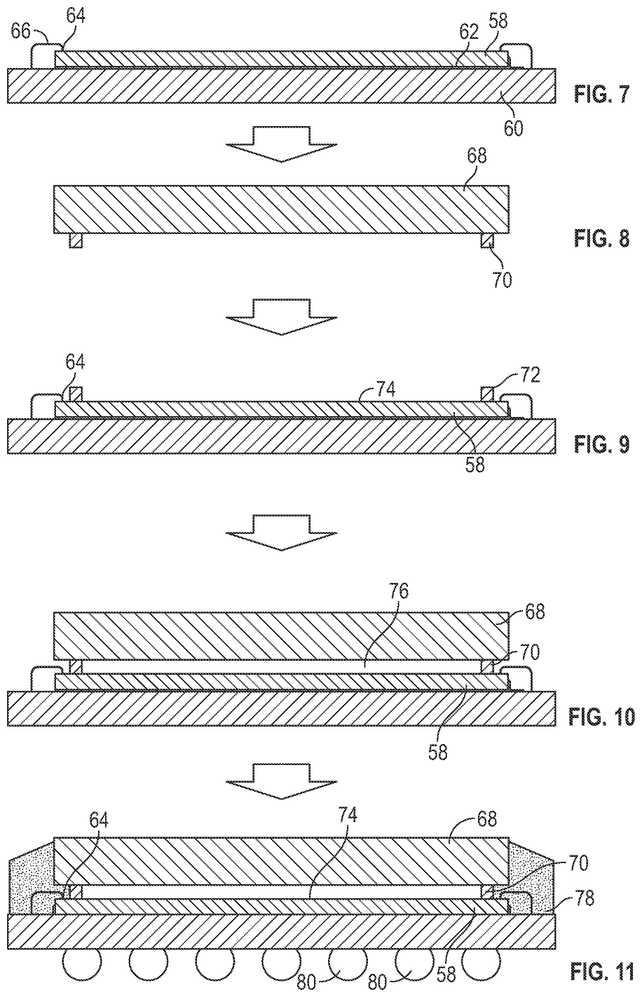

Referring to FIG. 11, the image sensor die 58 is illustrated following application of mold compound 78 around the sidewalls/edges of the electromagnetic radiation transmissive cover 68, dam 70, and image sensor die 58. Balls 80 have also been attached to pads on the substrate 60 using any process disclosed in this document (though balls may not be used in other implementations in favor of any other interconnect solution disclosed herein). Where the mold compound 78 is also electromagnetic radiation optically opaque to the wavelength of electromagnetic radiation the pixel array 74 is designed to receive, the placement of the dam 70 between the wirebonds 64 and the pixel array 74 ensures minimal reflected light can encounter the pixel array 74. In this image sensor package implementation, because the adhesive material 72 is only thermally cured, the issue of ultraviolet light curing with the adhesive material used in the image sensor package of FIG. 1 is also eliminated. Also, because of the presence of the dam 70, a much smaller amount of adhesive material relative to the implementation of FIG. 1 is needed to complete the formation of a fixed bond between the electromagnetic radiation transmissive cover and the image sensor die which aids in the thermal curing process.

In places where the description above refers to particular implementations of image sensor packages and implementing components, sub-components, methods and sub-methods, it should be readily apparent that a number of modifications may be made without departing from the spirit thereof and that these implementations, implementing components, sub-components, methods and sub-methods may be applied to other image sensor packages.

What is claimed is:

1. An image sensor package comprising:
an image sensor die;
an electromagnetic radiation transmissive cover coupled over the image sensor die; and
a dam between the image sensor die and the electromagnetic radiation transmissive cover, the dam comprising a colored additive;
wherein the dam forms a space between the image sensor die and the electromagnetic radiation transmissive cover.

2. The package of claim 1, wherein the colored additive makes the dam optically opaque to one or more wavelengths of electromagnetic radiation detected by the image sensor die.

3. The package of claim 1, wherein the colored additive makes the dam optically opaque to ultraviolet light wavelengths.

4. The package of claim 1, wherein the colored additive makes the dam optically opaque to infrared light wavelengths.

5. The package of claim 1, wherein the colored additive makes the dam optically opaque to visible light wavelengths.

6. The package of claim 1, wherein the dam fixedly couples the image sensor die and the electromagnetic radiation transmissive cover together.

7. The package of claim 1, further comprising a substrate coupled to the image sensor die.

8. The package of claim 1, further comprising an adhesive material that fixedly couples the image sensor die, the dam, and the electromagnetic radiation transmissive cover together.

9. A method of forming an image sensor package, the method comprising:
providing an image sensor die;
forming a dam on an electromagnetic radiation transmissive cover;
placing the electromagnetic radiation transmissive cover over the image sensor die;
fixedly coupling the image sensor die to the electromagnetic radiation transmissive cover by curing a material of the dam; and
preventing one or more wavelengths of light from passing through the dam using a colored additive comprised in the dam.

10. The method of claim 9, further comprising coupling a substrate to the image sensor die.

11. The method of claim 9, further comprising applying a mold compound to the image sensor die, the dam, and the electromagnetic radiation cover.

12. The method of claim 9, wherein the colored additive makes the dam optically opaque to ultraviolet light wavelengths.

13. The method of claim 9, wherein the colored additive makes the dam optically opaque to infrared light wavelengths.

14. The method of claim 9, wherein the colored additive makes the dam optically opaque to visible light wavelengths.

15. A method of forming an image sensor package, the method comprising:
providing an image sensor die;
forming a dam on an electromagnetic radiation transmissive cover;
applying an adhesive material to the image sensor die;
placing the electromagnetic radiation transmissive cover over the image sensor die;
fixedly coupling the image sensor die to the electromagnetic radiation transmissive cover by curing the adhesive material; and
preventing one or more wavelengths of light from passing through the dam using a colored additive comprised in the dam.

16. The method of claim 15, further comprising coupling a substrate to the image sensor die.

17. The method of claim 15, further comprising applying a mold compound to the image sensor die, the dam, and the electromagnetic radiation cover.

18. The method of claim 15, wherein the colored additive makes the dam optically opaque to one of infrared light wavelengths or ultraviolet light wavelengths.

19. The method of claim 15, wherein curing the adhesive material further comprises only thermally curing the adhesive material.

20. The method of claim 15, wherein the colored additive makes the dam optically opaque to visible light wavelengths.
